(19) United States
(12) Patent Application Publication
(10) Pub. No.: US 2025/0248235 A1
(43) Pub. Date: Jul. 31, 2025

(54) Display Substrate and Preparation Method Therefor, and Display Apparatus

(71) Applicants: Hefei Xinsheng Optoelectronics Technology Co., Ltd., Hefei, Anhui (CN); BOE Technology Group Co., Ltd., Beijing (CN)

(72) Inventors: Yu AI, Beijing (CN); Xuewu XIE, Beijing (CN); Xinyu LI, Beijing (CN); Shi SUN, Beijing (CN); Yubao KONG, Beijing (CN); Hao LIU, Beijing (CN); Bowen LIU, Beijing (CN); Weidong YIN, Beijing (CN)

(21) Appl. No.: 18/694,961

(22) PCT Filed: Aug. 30, 2023
(86) PCT No.: PCT/CN2023/115921

§ 371 Date: Mar. 23, 2024

(51) Int. Cl. H10K 59/126; H10D 86/40; H10D 86/60; H10K 59/12; H10K 59/121; H10K 59/131; H10K 59/38; H10K 59/80

(52) U.S. Cl. CPC H10K 59/126; H10K 59/1201; H10K 59/1213; H10K 59/131; H10K 59/38; H10K 59/8792; H10D 86/441; H10D 86/60

(57) ABSTRACT

A display substrate and a preparation method therefor, and a display apparatus. The display substrate includes a base substrate (101), a drive circuit layer (102) and a light emitting structure layer (105). The drive circuit layer (102) includes at least one pixel drive circuit, the at least one pixel drive circuit includes at least one transistor, the transistor at least includes an active layer (206), and the drive circuit layer (102) further includes at least one insulating layer located on a side of the active layer (206) away from the base substrate (101). The light emitting structure layer (105) includes at least one light emitting device. The display substrate further includes a light shielding structure (108), at least a portion of the light shielding structure (108) is located in an opening provided in the at least one insulating layer, and the light shielding structure (108) is configured to block light emitted by the at least one light emitting device from being emitted to a channel region (208) of the at least one active layer (206).

### CROSS-REFERENCE TO RELATED APPLICATION

The present application is a U.S. National Phase Entry of International Application No. PCT/CN2023/115921 having an international filing date of Aug. 30, 2023. Contents of the above-identified application should be interpreted as being incorporated into the present application by reference.

### TECHNICAL FIELD

The present disclosure relates to, but is not limited to, the field of display technology, and particularly relates to a display substrate and a preparation method therefor, and a display apparatus.

### BACKGROUND

An organic light-emitting diode (OLED) panel is an active light-emitting display device, which has the advantages of self-luminescence, wide viewing angle, high contrast, full-color display, light weight, small thickness, low power consumption, high reaction speed and the like, and can realize flexible display. It is the most promising display device.

### SUMMARY

The following is a summary of subject matters described herein in detail. This summary is not intended to limit the protection scope of the claims.

Embodiments of the present disclosure provide a display substrate, and a preparation method therefor, and a display apparatus.

In one aspect, an embodiment of the present disclosure provides a display substrate. The display substrate includes a base substrate, a drive circuit layer located on one side of the base substrate, and a light emitting structure layer located on a side of the drive circuit layer away from the base substrate. The drive circuit layer includes at least one pixel drive circuit, the at least one pixel drive circuit includes at least one transistor, the transistor at least includes an active layer, and the drive circuit layer further includes at least one insulating layer located on a side of the active layer away from the base substrate. The light emitting structure layer includes at least one light emitting device.

The display substrate further includes a light shielding structure, at least a portion of the light shielding structure is located in an opening provided in the at least one insulating layer, and the light shielding structure is configured to block light emitted by the at least one light emitting device from being emitted to a channel region of at least one active layer.

In an exemplary embodiment, the active layer further includes a first region and a second region located on opposite sides of the channel region; and the light shielding structure is located between the active layer and the light emitting structure layer.

The light shielding structure includes at least one of a first light shielding portion and a second light shielding portion, an orthographic projection of the first light shielding portion on the display substrate is located within an orthographic projection of the first region on the display substrate, and an orthographic projection of the second light shielding portion on the display substrate is located within an orthographic projection of the second region on the display substrate.

In an exemplary embodiment, the at least one insulating layer is provided with at least one opening, and the at least one opening includes at least one of a first opening and a second opening. An orthographic projection of the first opening on the display substrate is located within an orthographic projection of the first region on the display substrate, and an orthographic projection of the second opening on the display substrate is located within an orthographic projection of the second region on the display substrate.

At least a portion of the first light shielding portion is located within the first opening, and at least a portion of the second light shielding portion is located within the second opening.

In an exemplary embodiment, a side of the first light shielding portion close to the active layer is in contact with the first region, and a side of the first light shielding portion away from the active layer is flush with a side of the at least one insulating layer away from the active layer.

In an exemplary embodiment, a side of the second light shielding portion close to the active layer is in contact with the second region, and a side of the second light shielding portion away from the active layer is flush with a side of the at least one insulating layer away from the active layer.

In an exemplary embodiment, the display substrate further includes a color film structure layer located between the drive circuit layer and the light emitting structure layer. The color film structure layer includes a light shielding layer and a color filter. The light shielding layer is provided in a same layer as the color filter.

In an exemplary embodiment, the light shielding layer includes a black matrix, and at least a portion of the light shielding structure and the black matrix are of an interconnected integral structure.

In an exemplary embodiment, two adjacent color filters partially overlap and form an overlapping region located between two adjacent light emitting devices in a direction perpendicular to a plane of the display substrate.

In an exemplary embodiment, the light emitting device includes a first electrode, an organic light emitting layer and a second electrode which are stacked; and the first electrode is closer to the base substrate than the second electrode.

The first electrode is connected to the active layer via a connection electrode, and a portion of the connection electrode is reused as at least a portion of the light shielding structure.

In an exemplary embodiment, the connection electrode includes a first connection electrode and a second connection electrode which are stacked, and the first connection electrode is closer to the base substrate than the second connection electrode. A first end of the first connection electrode is connected to the active layer, a second end of the first connection electrode is connected to the second connection electrode, and the second connection electrode is connected to the first electrode.

Portions of the first connection electrode and the second connection electrode are reused as at least a portion of the light shielding structure.

In an exemplary embodiment, the connection electrode includes a first connection electrode and a second connection electrode which are stacked, and the first connection electrode is closer to the base substrate than the second connection electrode. A first end of the first connection electrode is connected to the active layer, a second end of the first connection electrode is connected to the second connection electrode, and the second connection electrode is connected to the first electrode.

The first connection electrode is reused as at least a portion of the light shielding structure.

In an exemplary embodiment, the second connection electrode and the first electrode are of an interconnected integral structure.

In an exemplary embodiment, the light emitting device includes a first electrode, an organic light emitting layer and a second electrode which are stacked. The first electrode is closer to the base substrate than the second electrode. The light emitting device further includes a pixel definition layer provided with a pixel opening, and the pixel opening exposes at least a portion of a surface of the first electrode.

At least a portion of the light shielding structure and the pixel definition layer are of an interconnected integral structure; or at least a portion of the light shielding structure and the organic light emitting layer are of an interconnected integral structure; or at least a portion of the light shielding structure and the second electrode are of an interconnected integral structure.

In an exemplary embodiment, the light shielding structure includes a light shielding block. The drive circuit layer includes a first conductive layer located on a side of the base substrate and a semiconductor layer located on a side of the first conductive layer away from the base substrate. The first conductive layer includes at least one light shielding block, the semiconductor layer includes at least one active layer, and an orthographic projection of the at least one light shielding block on the display substrate at least partially overlaps an orthographic projection of the channel region of the at least one active layer on the display substrate.

In an exemplary embodiment, the orthographic projection of the light shielding block on the display substrate includes the orthographic projection of the channel region of the active layer on the display substrate.

In an exemplary embodiment, the drive circuit layer includes a first conductive layer located on a side of the base substrate, a semiconductor layer located on a side of the first conductive layer away from the base substrate, and a second conductive layer located on a side of the semiconductor layer away from the base substrate. The semiconductor layer includes at least one active layer, and the second conductive layer includes a gate of the transistor.

An orthographic projection of the gate on the display substrate at least partially overlaps an orthographic projection of the channel region of the active layer on the display substrate.

In an exemplary embodiment, the orthographic projection of the gate on the display substrate includes the orthographic projection of the channel region of the active layer on the display substrate.

In an exemplary embodiment, the light shielding structure includes a light shielding block, and the first conductive layer includes at least one light shielding block. The orthographic projection of the gate on the display substrate, the orthographic projection of the channel region of the active layer on the display substrate and an orthographic projection of the light shielding block on the display substrate are at least partially overlapped.

In another aspect, an embodiment of the present disclosure provides a display apparatus, including the display substrate described in any one of the above embodiments.

In still another aspect, an embodiment of the present disclosure provides a preparation method for a display substrate for preparing the display substrate of any of the above embodiments.

The display substrate provided by the embodiment of the present disclosure may utilize the light shielding structure to shield the light emitted from the light emitting device to the channel region of the active layer, which may improve the problem of the negative drift of the transistor threshold voltage, avoid the afterimage of the display substrate, and improve the yield of the display product.

Other aspects of the present disclosure may be comprehended after the drawings and the detailed description are read and understood.

### BRIEF DESCRIPTION OF DRAWINGS

The drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of one or more components in the drawings do not reflect actual scales, and are only intended to schematically describe contents of the present disclosure.

FIG. 1 is a schematic diagram of a line afterimage appearing on a display screen of a display product;

FIG. 2 is a schematic diagram of a structure of a display apparatus according to an embodiment of the present disclosure;

FIG. 3 is a schematic diagram of a planar structure of a display substrate according to an embodiment of the present disclosure;

FIG. 4 is a schematic diagram of a sectional structure of a display substrate according to an embodiment of the present disclosure;

FIGS. 5A to 5M are schematic diagrams of a preparation process of a display substrate according to an embodiment of the present disclosure;

FIG. 6 is a schematic diagram of a sectional structure of a display substrate according to another embodiment of the present disclosure;

FIG. 7 is a schematic diagram of a sectional structure of a display substrate according to still another embodiment of the present disclosure;

FIG. 8 is a schematic diagram of a sectional structure of a display substrate according to yet another embodiment of the present disclosure;

FIG. 9 is a schematic diagram of a sectional structure of a display substrate according to still another embodiment of the present disclosure; and

FIGS. 10A to 10F are schematic diagrams of a preparation process of a display substrate according to yet another embodiment of the present disclosure.

### REFERENCE NUMBERS

101—base substrate, 102—drive circuit layer, 201—first insulating layer, 202—second insulating layer, 203—third insulating layer, 204—fourth insulating layer, 205—light shielding block, 206—active layer, 207—gate, 208—channel region, 209—first region, 210—second region, 211—first connection electrode, 212—second connection electrode; and
103—color film structure layer, 301—black matrix, 302—color filter, 104—first encapsulation layer, 105—light emitting structure layer, 501—anode, 502—organic light emitting layer, 503—cathode, 504—pixel definition layer, 504-1 pixel opening, 106—second encapsulation layer, 107—cover layer, 108—light shielding structure, 801—first light shielding portion, 802—second light shielding portion.

### DETAILED DESCRIPTION

Embodiments of the present disclosure will be described in detail below with reference to the drawings. Implementations may be implemented in multiple different forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the drawings schematically illustrate ideal examples, and a mode of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the present disclosure, “a plurality of” means two or more than two.

In the present disclosure, for convenience, expressions such as “middle”, “upper”, “lower”, “front”, “rear”, “vertical”, “horizontal”, “top”, “bottom”, “inner” and “outer” for indicating orientation or positional relationship are employed to explain the positional relationships between the constituent elements with reference to the drawings, which are only employed for ease of describing the specification and simplifying the description, but do not indicate or imply that the referred device or element must have a particular orientation, is constructed and operate in a particular orientation, and therefore cannot be construed as limitations on the present disclosure. The positional relationships between the constituent elements are changed as appropriate based on directions for describing the constituent elements. Therefore, appropriate replacements based on situations are allowed, and the positional relationships are not limited to the expressions described in the specification.

In the present disclosure, the terms “mounting”, “join” and “connection” are to be understood broadly, unless otherwise expressly specified and defined. For example, it may be a fixed connection, or a detachable connection, or an integral connection; it may be a mechanical connection or an electrical connection; it may be a direct connection, or an indirect connection through an intermediate, or an internal communication between two elements. Those of ordinary skills in the art may understand meanings of the aforementioned terms in the present disclosure according to situations.

In the present disclosure, “electric connection” includes a case where constituent elements are connected through an element with a certain electrical effect. “An element with a certain electrical function” is not particularly limited as long as electrical signals may be transmitted between the connected constituent elements. Examples of the “element with a certain electrical effect” not only include electrodes and wirings, but also include switching elements such as transistors, resistors, inductors, capacitors, other elements with one or more functions, etc.

In the present disclosure, a transistor refers to an element including at least three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region and the source electrode. In the present disclosure, the channel region refers to a region through which a current mainly flows.

In the present disclosure, a first electrode may be a drain electrode, and a second electrode may be a source electrode. Alternatively, a first electrode may be a source electrode, and a second electrode may be a drain electrode. In cases that transistors with opposite polarities are used, or a current direction changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the present disclosure, “film” and “layer” are interchangeable. For example, a “conductive layer” may be replaced with a “conductive film” sometimes. Similarly, an “insulating film” may be replaced with an “insulating layer” sometimes.

In the present disclosure, “about” and “approximately” means that a boundary is defined not so strictly and numerical values within process and measurement error ranges are allowed.

Triangle, rectangle, trapezoid, pentagon, hexagon and the like in the present disclosure are not strictly defined, and they may be approximate triangle, rectangle, trapezoid, pentagon, hexagon and the like. There may be some small deformations caused by tolerance, and there may be chamfer, arc edge, deformation, etc.

One of the development trends of the existing large-size display products is to improve the brightness of display products, especially to improve the peak brightness of display products. An OLED panel includes a plurality of light emitting units, and each light emitting unit includes an organic light emitting layer, which emits light of corresponding colors under the drive of a voltage. When a display product plays the same picture for a long time, the screen burning problem will occur, which may also be called bad afterimage. The so-called afterimage is image residue, which is usually divided into area afterimage and line afterimage. Therefore, in the process of product development, afterimage test is a very important evaluation item.

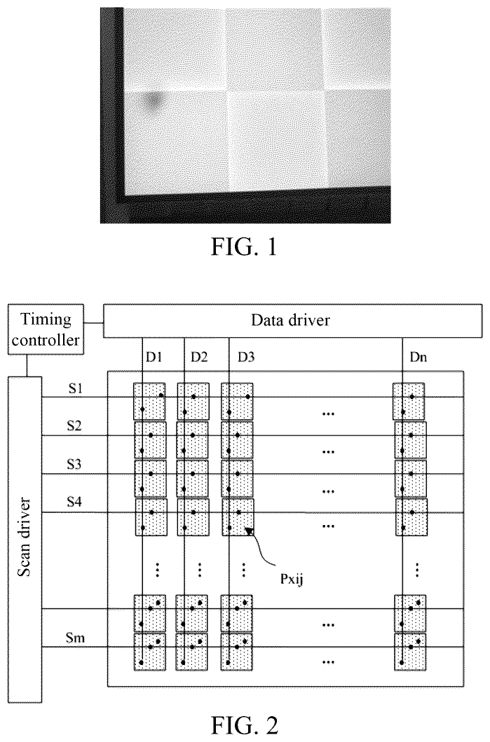

During the afterimage test of the display product, the inventor of the present application found that the display product will have a phenomenon of local illumination of the display screen as shown in FIG. 1, which may also be called line afterimage. In the actual production process, in order to improve the yield of display products, it is necessary to analyze the causes of line afterimage, and to improve or completely solve the problem of line afterimage. According to the analysis of the image, it is known that a threshold voltage (Vth) of a thin film transistor is negatively drifted because the light emitted by the light emitting unit of the display product partially irradiates the thin film transistor, which causes the line afterimage phenomenon on the display screen and leads to the low yield of the display products.

Therefore, an embodiment of the present disclosure provides a display substrate. The display substrate includes a base substrate, a drive circuit layer located on a side of the base substrate, and a light emitting structure layer located on a side of the drive circuit layer away from the base substrate. The drive circuit layer includes at least one pixel drive circuit, the at least one pixel drive circuit includes at least one transistor, the transistor at least includes an active layer, and the drive circuit layer further includes at least one insulating layer located on a side of the active layer away from the base substrate. The light emitting structure layer includes at least one light emitting device. The display substrate further includes a light shielding structure, at least a portion of the light shielding structure is located in an opening of the at least one insulating layer, and the light shielding structure is configured to block light emitted by the at least one light emitting device from being emitted to a channel region of at least one active layer.

The display substrate provided by the embodiment of the present disclosure may utilize the light shielding structure to shield the light emitted from the light emitting device to the channel region of the active layer, which may improve or solve the problem of the negative drift of the transistor threshold voltage, avoid the afterimage problem of the display substrate, and improve the yield of the display products.

FIG. 2 is a schematic diagram of a structure of a display apparatus according to an embodiment of the present disclosure. As shown in FIG. 2, an OLED display apparatus may include a timing controller, a data driver, a scan driver, and a pixel array. The timing controller is connected to the data driver and the scan driver, respectively. The data driver is connected to a plurality of data signal lines (D1 to Dn), respectively, and the scan driver is connected to a plurality of scan signal lines (Si to Sm), respectively. The pixel array may include a plurality of sub-pixels Pxij. Each sub-pixel Pxij may be connected to a corresponding data signal line and a corresponding scan signal line, and i and j may be natural numbers. At least one sub-pixel Pxij may at least include a circuit unit and a display unit, the circuit unit may at least include a pixel drive circuit connected to the scan signal line and the data signal line, respectively, and the display unit may at least include a light emitting device connected to the pixel drive circuit of the circuit unit. A sub-pixel Pxij may refer to a sub-pixel whose pixel drive circuit is connected to an i-th scan signal line and a j-th data signal line.

In an exemplary embodiment, the timing controller may provide a control signal and a gray scale value suitable for the specification of the data driver to the data driver, and may provide a clock signal, a scan start signal, and the like suitable for the specification of the scan driver to the scan driver. The data driver may generate a data voltage to be provided to the data signal lines D1, D2, D3, . . . , and Dn using the gray scale value and the control signal that are received from the timing controller. For example, the data driver may sample the gray scale value using the clock signal and apply a data voltage corresponding to the gray scale value to the data signal lines D1 to Dn by taking a pixel row as a unit, and n may be a natural number. The scan driver may generate a scan signals to be provided to the scan signal lines S1, S2, S3, . . . , and Sm by receiving the clock signal, the scan start signal and the like from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting a scan start signal provided in a form of an on-level pulse to a next-stage circuit under control of the clock signal, and m may be a natural number. In an exemplary embodiment, the pixel array may be provided on the display substrate.

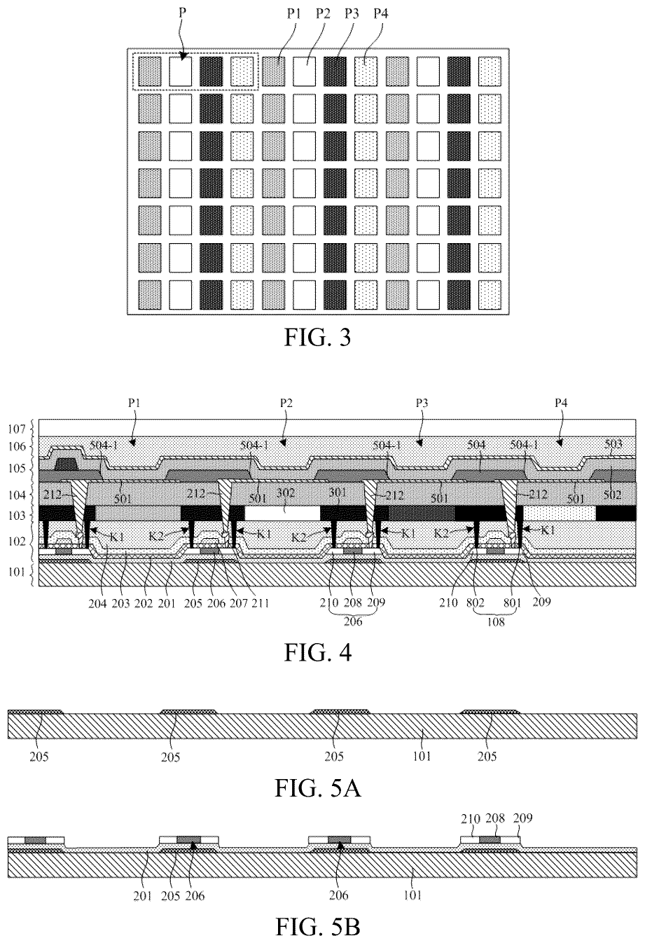

FIG. 3 is a schematic diagram of a planar structure of a display substrate according to an embodiment of the present disclosure. As shown in FIG. 3, the display substrate may include a plurality of pixel units P arranged in a matrix manner, and at least one pixel unit P may include a plurality of sub-pixels. For example, at least one of the plurality of pixel units P may include a first sub-pixel P1 emitting a first color light, a second sub-pixel P2 emitting a second color light, a third sub-pixel P3 emitting a third color light, and a fourth sub-pixel P4 emitting a fourth color light. Each of the four sub-pixels may include a circuit unit and a light emitting device. The circuit unit may include a pixel drive circuit which is respectively connected to a scan signal line and a data signal line, and the pixel drive circuit is configured to receive a data voltage transmitted by the data signal line and output a corresponding current to the light emitting device under control of the scan signal line. The light emitting device in each pixel unit is connected to a pixel drive circuit of a sub-pixel where the light emitting device is located, and the light emitting device is configured to emit light with corresponding brightness in response to a current output by the pixel drive circuit of the sub-pixel where the light emitting device is located.

In an exemplary embodiment, the first sub-pixel P1 may be a Red sub-pixel (R) emitting red light, the second sub-pixel P2 may be a White sub-pixel (W) emitting white light, the third sub-pixel P3 may be a Blue sub-pixel (B) emitting blue light, and the fourth sub-pixel P4 may be a Green sub-pixel (G) emitting green light.

In some exemplary embodiments, a shape of the sub-pixel may be a rectangle, a rhombus, a pentagon, or a hexagon. In an exemplary embodiment, the four sub-pixels may be arranged in a horizontal side-by-side manner to form an RWBG pixel arrangement. In another exemplary embodiment, the four sub-pixels may be arranged in a square, diamond, vertical side-by-side manner or the like, which is not limited here in the present disclosure.

FIG. 4 is a schematic diagram of a sectional structure of a display substrate according to an embodiment of the present disclosure. As shown in FIG. 4, a structure of four sub-pixels of the display substrate is schematically illustrated. As shown in FIG. 4, in a plane perpendicular to the display substrate, the display substrate includes a base substrate 101, a drive circuit layer 102 provided on a side of the base substrate 101, a color film structure layer 103 provided on a side of the drive circuit layer 102 away from the base substrate 101, a first encapsulation layer 104 provided on a side of the color film structure layer 103 away from the base substrate 101, a light emitting structure layer 105 provided on a side of the first encapsulation layer 104 away from the base substrate 101, a second encapsulation layer 106 provided on a side of the light emitting structure layer 105 away from the base substrate 101, and a cover plate layer 107 provided on a side of the second encapsulation layer 106 away from the base substrate 101. The drive circuit layer 102 may include a plurality of circuit units, and the light emitting structure layer 105 may include a plurality of light emitting devices. In some possible implementations, the display substrate may include other film layers, which is not limited here in the present disclosure.

In an exemplary embodiment, the base substrate 101 may be a rigid base substrate, or may be a flexible base substrate, or may be a silicon wafer. In an exemplary embodiment, the rigid base substrate may be made of a material such as glass or quartz, and the flexible base substrate may be made of a material such as polyimide (PI) or polyethylene terephthalate (PET). The flexible base substrate may be a monolayer structure, or may be a laminated structure consisting of an inorganic material layer and a flexible material layer. However, embodiments of the present disclosure are not limited thereto.

In an exemplary embodiment, the drive circuit layer 102 of each sub-pixel may include at least one circuit unit. The circuit unit may at least include a pixel drive circuit composed of at least one transistor. In some examples, the pixel drive circuit may further include at least one storage capacitor. In an example, the pixel drive circuit may be of 3T1C, 4T1C, 5T1C, 5T2C, 6T1C, 7T1C, 8T1C, or 9T2C structure or the like, with the number before T representing a quantity of transistors and the number before C representing a quantity of storage capacitors. As shown in FIG. 4, the pixel drive circuit in an exemplary embodiment of the present disclosure is exemplified only by including one transistor. However, embodiments of the present disclosure are not limited to the structure and form of the pixel drive circuit.

In an exemplary embodiment, as shown in FIG. 4, the drive circuit layer 102 of each sub-pixel may include a first conductive layer provided on a side of the base substrate 101, a first insulating layer 201 provided on a side of the first conductive layer away from the base substrate 101, a semiconductor layer provided on a side of the first insulating layer 201 away from the base substrate 101, a second insulating layer 202 provided on a side of the semiconductor layer away from the base substrate 101, a second conductive layer provided on a side of the second insulating layer 202 away from the base substrate 101, a third insulating layer 203 provided on a side of the second conductive layer away from the base substrate 101, a third insulating layer provided on a side of the third insulating layer 203 away from the base substrate 101, and a fourth insulating layer 204 provided on a side of the third conductive layer away from the base substrate 101. In an embodiment of the present disclosure, the first insulating layer 201 may also be referred to as a buffer layer, the second insulating layer 202 may also be referred to as a gate insulating (GI) layer, the third insulating layer 203 may also be referred to as an interlayer insulating (ILD) layer, and the fourth insulating layer 204 may also be referred to as a planarization (PLN) layer. As shown in FIG. 4, the first conductive layer may include a single layer or a plurality of layers, for example, including a transparent ITO layer and a metal layer. The metal layer may serve as a signal trace. The first conductive layer may include a light shielding block 205 of the transistor. The semiconductor layer may include an active layer 206 of the transistor. The second conductive layer may include a gate 207 of the transistor. The third conductive layer may include a first connection electrode 211 configured to connect the light emitting device with the pixel drive circuit. As shown in FIG. 4, a second end of the first connection electrode 211 may be connected to an anode of the light emitting device, and a first end of the first connection electrode 211 may be connected to the transistor-conductive active layer 206.

In an exemplary embodiment, the first conductive layer, the second conductive layer, and the third conductive layer may be made of metallic material(s), such as any one or more of molybdenum (Mo), aluminum (Al), copper (Cu) and titanium (Ti). Alternatively, the first conductive layer, the second conductive layer, and the third conductive layer may be made of an alloy material of metallic materials such as molybdenum (Mo), aluminum (Al), copper (Cu), and titanium (Ti), for example, an aluminum-neodymium alloy (AlNd) or a molybdenum-niobium alloy (MoNb). The first conductive layer, the second conductive layer, and the third conductive layer may be a single-layer structure, or a multi-layer composite structure, such as Ti/Al/Ti or the like.

In an exemplary embodiment, the first insulating layer, the second insulating layer, and the third insulating layer may be made of an inorganic material, and the inorganic materials may include any one or more of silicon oxynitride (SiOxNy), silicon nitride (SiNx), silicon oxide (SiOx), and the like. The fourth insulating layer may be made of an organic material, and the organic material may include one of polyimide (PI), polyacrylate, polyphenylene sulfide, polyaryl ester, cellulose acetate propionate, polyethylene naphthalate (PEN), polyethylene terephthalate (PET), polyethersulfone resin (PES), polycarbonate (PC), polyetherimide (PEI), cycloolefin polymer (COP), silica gel resin, polyaryl compound (PAR) or glass fiber reinforced plastic (FRP) or other polymers, or a mixture of a plurality of polymers.

In some possible exemplary embodiments, a passivation (PVX) layer may further be included between the third insulating layer and the fourth insulating layer. The passivation layer may be made of an inorganic material, which may include any one or more of silicon oxynitride (SiOxNy), silicon nitride (SiNx), silicon oxide (SiOx), and the like.

In an exemplary embodiment, the first conductive layer may further include a data signal line. The data signal line may be provided in the same layer as the light shielding block 205, which may simplify the preparation process of the display substrate, reduce the quantity of film layers of the display substrate, and reduce the preparation cost of the display substrate.

In an exemplary embodiment, the first conductive layer may further include a first electrode plate of the storage capacitor, the second conductive layer may further include a second electrode plate of the storage capacitor, and an orthographic projection of the first electrode plate on the display substrate at least partially overlaps an orthographic projection of the second electrode plate on the display substrate. Alternatively, the second conductive layer may further include a first electrode plate of the storage capacitor, and the third conductive layer may further include a second electrode plate of the storage capacitor.

In an exemplary embodiment, a material of the semiconductor layer may include an oxide semiconductor material. For example, the semiconductor layer may be made of one or more of amorphous indium gallium zinc oxide material (a-IGZO), zinc oxide nitride (ZnON), indium zinc tin oxide (IZTO) and the like. As shown in FIG. 4, an orthographic projection of the active layer 206 on the base substrate 101 may at least partially overlap an orthographic projection of the light shielding block 205 on the base substrate 101. For example, the orthographic projection of the active layer 206 on the base substrate 101 may include the orthographic projection of the light shielding block 205 on the base substrate 101.

In an exemplary embodiment, as shown in FIG. 4, the active layer 206 may include a channel region 208, and a first region 209 and a second region 210 which are located on opposite sides of the channel region 208. For example, in the process of preparing the display substrate, a part of the active layer 206 may be conductively processed so that the part of the active layer forms the first region 209 and the second region 210 respectively. The first region 209 of the active layer 206 may be used as a first electrode of the transistor which may be a source electrode or a drain electrode, and the second region 210 of the active layer 206 may be used as a second electrode of the transistor. However, embodiments of the present disclosure are not limited to the conductivization process of the semiconductor layer.

In an exemplary embodiment, as shown in FIG. 4, an orthographic projection of the channel region 208 of the active layer 206 on the base substrate 101 at least partially overlaps an orthographic projection of the light shielding block 205 on the base substrate 101. For example, the orthographic projection of the light shielding block 205 on the base substrate 101 may include the orthographic projection of the channel region 208 on the base substrate 101. By providing the light shielding block 205, the channel region 208 of the active layer 206 of the transistor may be shielded, and light may be prevented from being emitted to the transistor from one side of the base substrate, thereby avoiding affecting the characteristics of the transistor and reducing the yield of the display product.

In an exemplary embodiment, as shown in FIG. 4, an orthographic projection of the first region 209 and the second region 210 on the base substrate 101 may at least partially overlap an orthographic projection of the light shielding block 205 on the base substrate 101. For example, the orthographic projection of the first region 209 on the base substrate 101 may be within the orthographic projection of the light shielding block 205 on the base substrate 101. For example, the orthographic projection of the second region 210 on the base substrate 101 may be within the orthographic projection of the light shielding block 205 on the base substrate 101.

In an exemplary embodiment, as shown in FIG. 4, an orthographic projection of the gate 207 on the base substrate 101 may overlap both the orthographic projection of the active layer 206 of the semiconductor layer on the base substrate 101 and the orthographic projection of the light shielding block 205 on the base substrate 101. For example, the orthographic projection of the gate 207 on the base substrate 101 may include the orthographic projection of the channel region 208 of the active layer 206 on the base substrate 101. Alternatively, the orthographic projection of the gate 207 on the base substrate 101 may overlap the orthographic projection of the channel region 208 of the active layer 206 on the base substrate 101. By providing the relationship between the orthographic projection of the gate 207 on the base substrate 101 and the orthographic projection of the channel region 208 on the base substrate 101, the gate 207 may be used to shield at least part of the light directed to the channel region 208, thereby improving the reliability of the active layer and prolonging the service life of the display substrate.

In an exemplary embodiment, the second conductive layer may further include a scan signal line. The scan signal line may be provided in the same layer as the gate 207 of the transistor, thereby simplifying the film layer structure of the display substrate and reducing the preparation cost of the display substrate. For example, the scan signal line and the gate 207 may be of an interconnected integral structure. For example, the scan signal line may be in a shape of an extended line, and the gate 207 may protrude from the scan signal line and toward an extending direction of the scan signal line.

In an exemplary embodiment, the color film structure layer 103 may include a light shielding layer and a color filter (CF) 302. The light shielding layer may include a black matrix (BM) 301, or a portion where adjacent color filters (CF) 302 overlap. The light shielding layer may avoid crosstalk of light of different colors between adjacent sub-pixels. In an embodiment of the present disclosure, for example, taking the light shielding layer including a black matrix (BM) 301 as an example, the black matrix 301 may be provided around the color filter 302. The color filters 302 are arranged in the red sub-pixel, the white sub-pixel, the blue sub-pixel, and the green sub-pixel, respectively, to filter white light emitted from the light emitting device into red (R) light, white (W) light, blue (B) light, and green (G) light. The black matrix 301 may be located between adjacent color filters 302. For example, the black matrix (BM) 301 and the color filters (CF) 302 may be provided in the same layer, which may reduce a thickness of the display substrate.

In an exemplary embodiment, two adjacent color filters 302 partially overlap and form an overlapping region, and the overlapping region is located between two adjacent light emitting devices in a direction perpendicular to a plane of the display substrate. The overlapping region formed by two adjacent color filters may be used as a light shielding layer, which may simplify the preparation process of the display substrate as a whole and reduce the manufacturing cost.

In an exemplary embodiment, as shown in FIG. 4, at least one sub-pixel may include a light shielding structure 108. The light shielding structure 108 is configured to block light emitted by at least one light emitting device from being directed to the transistor. As shown in FIG. 4, for example, the four sub-pixels each include the light shielding structure 108.

In an exemplary embodiment, as shown in FIG. 4, the light shielding structure 108 may include at least one of a first light shielding portion 801 and a second light shielding portion 802. The first light shielding portion 801 may be configured to block light emitted by a light emitting device included in a sub-pixel where the light shielding structure 108 is located from being directed to a transistor included in the sub-pixel where the light shielding structure 108 is located. The second light shielding portion 802 may be configured to block light emitted by a light emitting device included in a sub-pixel adjacent to the sub-pixel where the light shielding structure 108 is located from being directed to a transistor included in the sub-pixel where the light shielding structure 108 is located. As shown in FIG. 4, taking the fourth sub-pixel P4 as an example, the first light shielding portion 801 may block light emitted by the light emitting device included in the fourth sub-pixel P4 from being directed to the transistor included in the fourth sub-pixel P4. The second light shielding portion 802 may block light emitted by the light emitting device included in the third sub-pixel P3 from being directed to the transistor included in the fourth sub-pixel P4.

In an exemplary embodiment, as shown in FIG. 4, at least a portion of the light shielding structure 108 and the black matrix 301 may be of an interconnected integral structure, so as to simplify the film layer structure of the display substrate, simplify the preparation process of the display substrate, and reduce the preparation cost of the display substrate. For example, the first light shielding portion 801 and the black matrix 301 may be of an interconnected integral structure. Alternatively, the second light shielding portion 802 and the black matrix 301 may be of an interconnected integral structure. Alternatively, the light shielding structure 108 and the black matrix 301 may be of an interconnected integral structure. In a possible exemplary embodiment, the light shielding structure 108 and the black matrix 301 may be prepared by different processes, and a material of the light shielding structure 108 and a material of the black matrix 301 may be different or the same.

In an exemplary embodiment, as shown in FIG. 4, an orthographic projection of the black matrix 301 on the display substrate may include an orthographic projection of the light shielding structure 108 on the display substrate, which may prevent the light shielding structure from occupying an area of the light emitting region of the sub-pixel and improve the aperture ratio of the display substrate.

In an exemplary embodiment, as shown in FIG. 4, the fourth insulating layer 204 may be provided with at least one first opening K1, which may penetrate the third insulating layer 203 and the second insulating layer 202 and expose a portion of a surface of the first region 209. At least a portion of the first light shielding portion 801 may be located within the first opening K1. For example, the first opening K1 may be a rectangular hole, a circular hole, a hexagonal hole, or the like.

In some possible exemplary embodiments, the fourth insulating layer 204 may be provided with at least one first opening K1. The first opening K1 does not penetrate the fourth insulating layer 204. Alternatively, the first opening K1 penetrates the fourth insulating layer 204 and exposes a portion of a surface of the third insulating layer 203 facing away from the base substrate 101. At least a portion of the first light shielding portion 801 may be located within the first opening K1, and the first light shielding portion 801 may be in contact with the portion of the surface of the third insulating layer 203 facing away from the base substrate 101.

In some possible exemplary embodiments, the fourth insulating layer 204 may be provided with at least one first opening K1. The first opening K1 penetrates the fourth insulating layer 204 and does not penetrate the third insulating layer 203, or the first opening K1 penetrates the third insulating layer 203 and exposes a portion of a surface of the second insulating layer 202 facing away from the base substrate 101. At least a portion of the first light shielding portion 801 may be located within the first opening K1, and the first light shielding portion 801 may be in contact with the portion of the surface of the second insulating layer 202 facing away from the base substrate 101.

In some possible exemplary embodiments, the fourth insulating layer 204 may be provided with at least one first opening K1. The first opening K1 penetrates the fourth insulating layer 204 and the third insulating layer 203 and does not penetrate the second insulating layer 202. At least a portion of the first light shielding portion 801 may be located within the first opening K1.

In an exemplary embodiment, as shown in FIG. 4, the fourth insulating layer 204 may be provided with at least one second opening K2. The second opening K2 may penetrate the third insulating layer 203 and the second insulating layer 202 and expose a portion of a surface of the second region 210. At least a portion of the second light shielding portion 802 may be located within the second opening K2. For example, the second opening K2 may be a rectangular hole, a circular hole, a hexagonal hole, or the like. Shapes of the second opening K2 and the first opening K1 may be the same or different.

In some possible exemplary embodiments, the fourth insulating layer 204 may be provided with at least one second opening K2. The second opening K2 does not penetrate the fourth insulating layer 204, or the second opening K2 penetrates the fourth insulating layer 204 and exposes a portion of a surface of the third insulating layer 203 facing away from the base substrate 101. At least a portion of the second light shielding portion 802 may be located within the second opening K2, and the second light shielding portion 802 may be in contact with the portion of the surface of the third insulating layer 203 facing away from the base substrate 101.

In some possible exemplary embodiments, the fourth insulating layer 204 may be provided with at least one second opening K2. The second opening K2 penetrates the fourth insulating layer 204 and does not penetrate the third insulating layer 203, or the second opening K2 penetrates the third insulating layer 203 and exposes a portion of a surface of the second insulating layer 202 facing away from the base substrate 101. At least a portion of the second light shielding portion 802 may be located within the second opening K2, and the second light shielding portion 802 may be in contact with the portion of the surface of the second insulating layer 202 facing away from the base substrate 101.

In some possible exemplary embodiments, the fourth insulating layer 204 may be provided with at least one second opening K2. The second opening K2 may penetrate the fourth insulating layer 204 and the third insulating layer 203 and does not penetrate the second insulating layer 202. At least a portion of the second light shielding portion 802 may be located within the second opening K2.

In an exemplary embodiment, as shown in FIG. 4, the first encapsulation layer 104 may be in a Thin Film Encapsulation (TFE) mode, which may ensure that external water vapor cannot enter the drive circuit layer 102. The first encapsulation layer 104 may be a single film layer structure or a composite film layer structure with two or more layers. In some examples, the first encapsulation layer 104 may include a first encapsulation sub-layer, a second encapsulation sub-layer, and a third encapsulation sub-layer which are stacked. The first encapsulation sub-layer and the third encapsulation sub-layer may be made of an inorganic material, the second encapsulation sub-layer may be made of an organic material, and the second encapsulation sub-layer may be provided between the first encapsulation sub-layer and the third encapsulation sub-layer.

In an exemplary embodiment, as shown in FIG. 4, the light emitting structure layer 105 may include a plurality of light emitting devices, which may be organic electroluminescent diodes (OLED). At least one light emitting device may include a first electrode, an organic light emitting layer 502, and a second electrode which are stacked. The first electrode may be an anode or a cathode. In an embodiment of the present disclosure, the first electrode as an anode and the second electrode as a cathode are taken as an example. The anode 501 may be connected to the first electrode (first region 209) of the transistor through a connection electrode, the connection electrode may include a second connection electrode 212 and a first connection electrode 211, the organic light emitting layer 502 is connected to the anode 501, the cathode 503 is connected to the organic light emitting layer 502, the cathode 503 may be connected to a power supply line, and the organic light emitting layer 502 may emit light under drive of the anode 501 and the cathode 503.

In an exemplary embodiment, the organic light emitting layer 502 may include a Light Emitting Layer (EML) and any one or more of a Hole Injection Layer (HIL), a Hole Transport Layer (HTL), an Electron Block Layer (EBL), a Hole Block Layer (HBL), an Electron Transport Layer (ETL), and an Electron Injection Layer (EIL). As shown in FIG. 4, for a light emitting device emitting white light, the organic light emitting layers of all sub-pixels may be common layers connected together.

In an exemplary embodiment, as shown in FIG. 4, the second connection electrode 212 and the anode 501 may be of an interconnected integral structure so that the film layer structure of the display substrate may be simplified and the preparation cost of the display substrate may be reduced.

In an exemplary embodiment, as shown in FIG. 4, an orthographic projection of the black matrix 301 on the display substrate may include orthographic projections of the second connection electrode 212 and the first connection electrode 211 on the display substrate, which may improve the area utilization rate of the display substrate and the aperture ratio of the display substrate.

In an exemplary embodiment, the anode 501 may be made of a transparent conductive material, such as indium tin oxide (ITO) or indium zinc oxide (IZO), which may avoid the loss of light emitted by the anode to the light emitting device and improve the light use efficiency of the display substrate.

In an exemplary embodiment, as shown in FIG. 4, the light emitting device may further include a pixel definition layer 504. The pixel definition layer 504 may be provided with a pixel opening 504-1 that exposes at least a portion of a surface of the anode 501. The pixel definition layer 504 may be made of polyimide, acrylic, polyethylene terephthalate, or the like.

In some possible exemplary embodiments, at least a portion of the light shielding structure 108 and the pixel definition layer 504 may be of an interconnected integral structure. For example, the second light shielding portion 802 and the pixel definition layer 504 may be of an interconnected integral structure. Alternatively, at least a portion of the light shielding structure 108 and the organic light emitting layer 502 may be of an interconnected integral structure. Alternatively, at least a portion of the light shielding structure 108 and the cathode 503 may be of an interconnected integral structure.

In an exemplary embodiment, shapes and areas of pixel openings of different sub-pixels may be different.

In an exemplary embodiment, shapes of the pixel openings of the four sub-pixels may be the same or different, and areas of the pixel openings of the four sub-pixels may be the same or different.

In an exemplary embodiment, a shape of the pixel opening in the display substrate may include any one or more of triangle, rectangle, trapezoid, parallelogram, pentagon, hexagon, circle and ellipse.

In an exemplary embodiment, the second encapsulation layer 106 may be in a Thin Film Encapsulation (TFE) mode, which may ensure that external water vapor cannot enter the light emitting structure layer 105. The second encapsulation layer 106 may be a single film layer structure or a composite film layer structure with two or more layers. In some examples, the second encapsulation layer 106 may include a fourth encapsulation sub-layer, a fifth encapsulation sub-layer, and a sixth encapsulation sub-layer which are stacked. The fourth encapsulation sub-layer and the sixth encapsulation sub-layer may be made of an inorganic material, the fifth encapsulation sub-layer may be made of an organic material, and the fifth encapsulation sub-layer may be provided between the fourth encapsulation sub-layer and the sixth encapsulation sub-layer.

In an exemplary embodiment, the cover plate layer 107 may be made of glass or plastic colorless polyimide with flexible characteristics.

The structure of the display substrate will be exemplified below by a preparation process of the display substrate. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, and the present disclosure is not limited thereto. A “thin film” refers to a layer of thin film made of a material on a base substrate by using deposition, coating, or another process. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. In an embodiment of the present disclosure, “being provided in the same layer” is being located in the same layer of the display substrate.

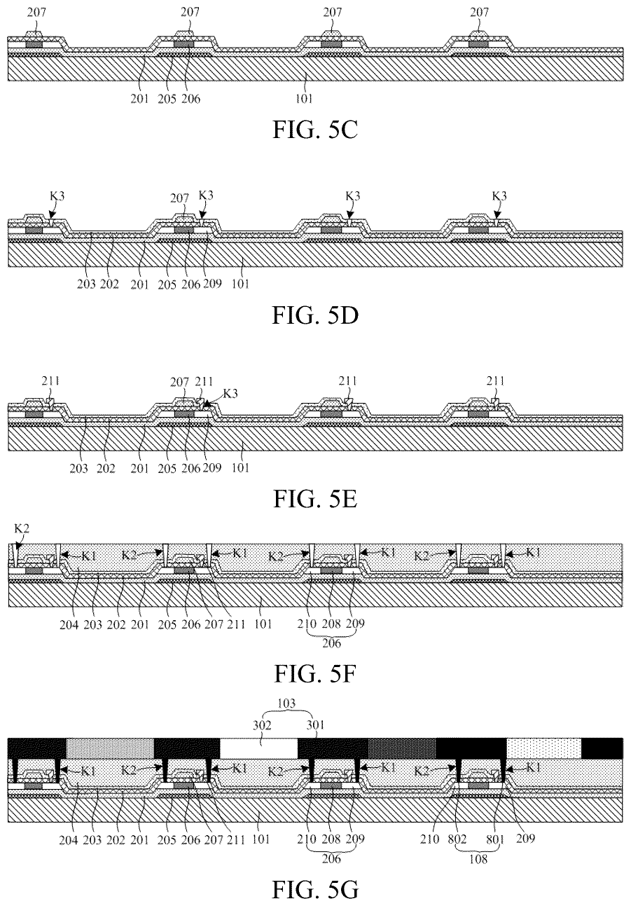

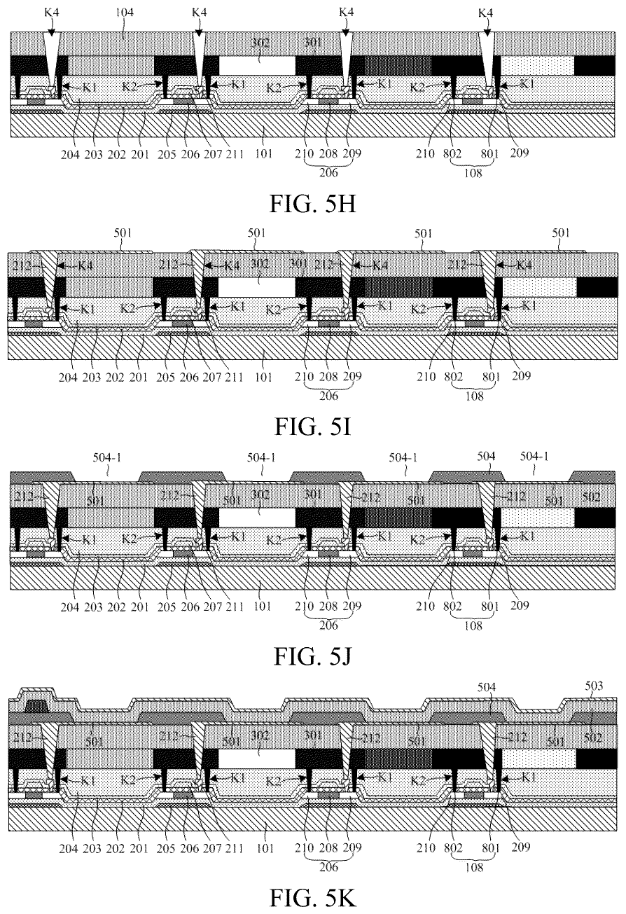

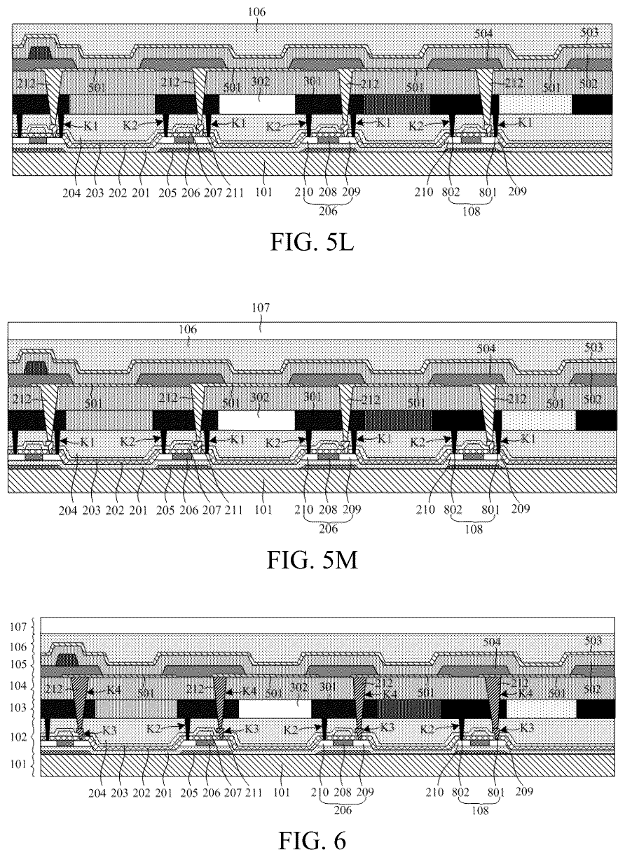

The preparation process of the display substrate may include the following steps. Taking the structure of the display substrate shown in FIG. 4 as an example, the preparation process of the display substrate is shown in FIGS. 5A to 5M:
(11) Providing a base substrate 101.
(12) Forming a pattern of a first conductive layer. Forming the pattern of the first conductive layer may include depositing a first conductive film on one side of the base substrate 101, and patterning the first conductive film by a patterning process, to form a pattern of a first conductive layer which is provided on one side of the base substrate 101. As shown in FIG. 5A, the first conductive layer may include a light shielding block 205, a data signal line, and the like.
(13) Forming a pattern of a semiconductor layer. Forming the pattern of the semiconductor layer may include sequentially depositing a first insulating film and a semiconductor film on the base substrate 101 on which the aforementioned pattern has been formed, and patterning the semiconductor film by a patterning process, to form a first insulating layer 201 provided on a side of the first conductive layer, and a pattern of a semiconductor layer provided on a side of the first insulating layer 201, as shown in FIG. 5B. The semiconductor layer may include an active layer 206 of a transistor.

Forming the pattern of the semiconductor layer may further include conducting a part of the active layer 206 such that portions of the active layer 206 form a first region 209 and a second region 210, respectively. For example, the first region 209 may be used as a first electrode of the transistor, and the second region 210 may be used as a second electrode of the transistor.
(14) Forming a pattern of a second conductive layer. Forming the pattern of the second conductive layer may include sequentially depositing a second insulating film and a second conductive film on the base substrate 101 on which the aforementioned patterns have been formed, and patterning the second conductive film by a patterning process, to form a second insulating film provided on a side of the semiconductor layer and a pattern of a second conductive layer located on a side of the second insulating film, as shown in FIG. 5C. The second conductive layer may include a gate 207 of a transistor, a scan signal line, and the like.
(15) Forming a pattern of a third insulating layer. Forming the pattern of the third insulating layer may include depositing a third insulating film on the base substrate 101 on which the aforementioned patterns have been formed, and patterning the third insulating film and the second insulating film by a patterning process, to form a pattern of a second insulating layer provided on a side of the semiconductor layer and a pattern of a third insulating layer provided on a side of the second conductive layer, as shown in FIG. 5D. The third insulating layer 203 may be provided with at least one third opening K3, which may penetrate the third insulating layer 203 and the second insulating layer 202 and expose a portion of a surface of the first region 209. The third opening K3 is configured such that a first connection electrode formed subsequently is connected to the first region 209 of the transistor via the third opening. In an example, an orthographic projection of the second insulating layer 202 on the display substrate may include an orthographic projection of the base substrate 101 on the display substrate. For example, the orthographic projection of the second insulating layer 202 on the display substrate overlaps the orthographic projection of the base substrate 101 on the display substrate. Alternatively, the orthographic projection of the second insulating layer 202 on the display substrate includes an orthographic projection of the active layer 206 on the display substrate, the orthographic projection of the second insulating layer 202 on the display substrate is within a range of the orthographic projection of the base substrate 101 on the display substrate, and the orthographic projection of the second insulating layer 202 on the display substrate does not overlap the orthographic projection of the base substrate 101 on the display substrate.
(16) Forming a pattern of a third conductive layer. Forming the pattern of the third conductive layer may include depositing a third conductive film on the base substrate 101 on which the aforementioned patterns have been formed, and patterning the third conductive film by a patterning process, to form a pattern of a third conductive layer provided on the third insulating layer 203, as shown in FIG. 5E. The third conductive layer may include a first connection electrode 211. At least a portion of the first connection electrode 211 may be located at the third opening K3, and the first connection electrode 211 may be connected to the first region 209 via the third opening K3.
(17) Forming a pattern of a fourth insulating layer. Forming the pattern of the fourth insulating layer may include depositing a fourth insulating film on the base substrate 101 on which the aforementioned patterns have been formed, and patterning the fourth insulating film by a patterning process, to form a pattern of a fourth insulating layer located on a side of the third conductive layer, as shown in FIG. 5F. The fourth insulating layer 204 may include at least one of a first opening K1 and a second opening K2. The first opening K1 may penetrate the third insulating layer 203 and the second insulating layer 202 and expose a portion of a surface of the first region 209, and the first opening K1 is configured such that at least a portion of a first light shielding portion formed subsequently is located within the first opening K1. The second opening K2 may penetrate the third insulating layer 203 and the second insulating layer 202 and expose a portion of a surface of the second region 210, and the second opening K2 is configured such that at least a portion of a second light shielding portion formed subsequently is located within the second opening K2.
(18) Forming a pattern of a color film structure layer. Forming the pattern of the color film structure layer may include coating a black pigment or depositing a black chromium (Cr) film on the base substrate 101 on which the aforementioned patterns have been formed, and patterning the black pigment or the black chromium film by a patterning process, to form a pattern of a black matrix located on a side of the fourth insulating layer 204, as shown in FIG. 5G.

At least a portion of the light shielding structure 108 and the black matrix 301 may be of an interconnected integral structure, which may simplify the film layer structure of the display substrate and reduce the preparation cost of the display substrate. The light shielding structure 108 may include at least one of a first light shielding portion 801 and a second light shielding portion 802. For example, the first light shielding portion 801 and the black matrix 301 may be of an interconnected integral structure. Alternatively, the second light shielding portion 802 and the black matrix 301 may be of an interconnected integral structure.

Forming the pattern of the color film structure layer may further include forming a pattern of a filter layer located on a side of the fourth insulating layer 204 by means of photolithography or the like on the base substrate 101 on which the aforementioned patterns have been formed. The pattern of the filter layer may include a plurality of color filters 302. As shown in FIG. 5G, the color filters 302 and the black matrix 301 are located on the same side of the fourth insulating layer 204, and an orthographic projection of the color filters 302 on the display substrate does not overlap an orthographic projection of the black matrix 301 on the display substrate. The color filters 302 are provided in the red sub-pixel, the white sub-pixel, the blue sub-pixel, and the green sub-pixel, respectively, and filter white light emitted from the light emitting device into red (R) light, white (W) light, blue (B) light, and green (G) light, respectively.
(19) Forming a pattern of a first encapsulation layer. Forming the pattern of the first encapsulation layer may include depositing a fifth insulating film on the base substrate 101 on which the aforementioned patterns have been formed, and patterning the fifth insulating film by a patterning process, to form a pattern of a first encapsulation layer located on a side of the color film structure layer, as shown in FIG. 5H. The first encapsulation layer 104 may include at least one fourth opening K4, which may penetrate the first encapsulation layer 104, the black matrix 301 and the fourth insulating layer 204 and expose a portion of a surface of the first connection electrode 211 so that at least a portion of a second connection electrode formed subsequently is located within the fourth opening K4, and that the second connection electrode is connected to the first connection electrode 211 via the fourth opening.
(20) Forming a pattern of a fourth conductive layer. Forming the pattern of the fourth conductive layer may include depositing a fourth conductive film on the base substrate 101 on which the aforementioned patterns have been formed, and patterning the fourth conductive film by a patterning process, to form a pattern of a fourth conductive layer provided on a side of the first encapsulation layer, as shown in FIG. 5I. The fourth conductive layer may include a second connection electrode 212, an anode 501, and the like. At least a portion of the second connection electrode 212 may be located within the fourth opening K4 and connected to the first connection electrode 211. The pattern of the fourth conductive layer may include an anode located in the first sub-pixel, an anode located in the second sub-pixel, an anode located in the third sub-pixel, and an anode located in the fourth sub-pixel.
(21) Forming a pattern of a pixel definition layer. Forming the pattern of the pixel definition layer may include coating a pixel definition film on the base substrate 101 on which the aforementioned patterns have been formed, and patterning the pixel definition film by a patterning process, to form a pattern of a pixel definition layer, the pixel definition layer 504 may at least include a pixel opening 504-1 located in each sub-pixel, as shown in FIG. 5J. The pixel opening 504-1 exposes at least a portion of a surface of the anode 501 such that a portion of an organic light emitting layer formed subsequently is in contact with the anode 501.
(22) Forming a pattern of a fifth conductive layer. Forming the pattern of the fifth conductive layer may include sequentially forming an organic light emitting film and a fifth conductive film on the base substrate 101 on which the aforementioned patterns have been formed, and patterning the fifth conductive film and the organic light emitting film by a patterning process, to form a pattern of an organic light emitting layer and a pattern of a fifth conductive layer located on a side of the pixel definition layer 504, as shown in FIG. 5K. The fifth conductive layer may include a cathode 503. For example, the fifth conductive layer may further include a power supply line, and the like. The anode 501, the organic light emitting layer 502 and the cathode 503 which are stacked to form a light emitting device. The organic light emitting layer 502 is connected to the anode 501, the cathode 503 is connected to the organic light emitting layer 502, and the organic light emitting layer 502 may emit light under drive of the anode 501 and the cathode 503.

In an exemplary embodiment, the fifth conductive layer may be made of metallic material(s), such as any one or more of molybdenum (Mo), aluminum (Al), copper (Cu), and titanium (Ti). Alternatively, the fifth conductive layer may be made of an alloy material of metallic materials such as molybdenum (Mo), aluminum (Al), copper (Cu), and titanium (Ti), for example, an aluminum-neodymium alloy (AlNd) or a molybdenum-niobium alloy (MoNb). The fifth conductive layer may be a single-layer structure or a multi-layer composite structure such as Ti/Al/Ti or the like.
(23) Forming a pattern of a second encapsulation layer. Forming the pattern of the second encapsulation layer may include depositing a sixth insulating film on the base substrate 101 on which the aforementioned patterns have been formed, and patterning the sixth insulating film by a patterning process, to form a pattern of a second encapsulation layer located on a side of the fifth conductive layer, as shown in FIG. 5L. An orthographic projection of the second encapsulation layer 106 on the display substrate may include an orthographic projection of the fifth conductive layer on the display substrate, which may prevent external water and oxygen from invading the light emitting structure layer and improve the reliability of the display substrate.
(24) Forming a cover plate layer. Forming the cover plate layer may include preparing a cover plate layer 107 on the base substrate 101 on which the aforementioned patterns have been formed, as shown in FIG. 5M. The cover plate layer 107 may be made of glass or plastic colorless polyimide with flexible properties.

FIG. 6 is a schematic diagram of a sectional structure of a display substrate according to another embodiment of the present disclosure. As shown in FIG. 6, in a plane perpendicular to the display substrate, each sub-pixel in the display substrate may include a base substrate 101, a drive circuit layer 102 provided on a side of the base substrate 101, a color film structure layer 103 provided on a side of the drive circuit layer 102 away from the base substrate 101, a first encapsulation layer 104 provided on a side of the color film structure layer 103 away from the base substrate 101, a light emitting structure layer 105 provided on a side of the first encapsulation layer 104 away from the base substrate 101, a second encapsulation layer 106 provided on a side of the light emitting structure layer 105 away from the base substrate 101, and a cover plate layer 107 provided on a side of the second encapsulation layer 106 away from the base substrate 101. The light emitting structure layer 105 may include a plurality of light emitting devices. The display substrate shown in FIG. 6 differs mainly from the aforementioned display substrate shown in FIG. 4 in that portions of the first connection electrode 211 and the second connection electrode 212 are reused as at least a portion of the light shielding structure 108. In a structure in which the light shielding structure 108 includes a first light shielding portion 801 and a second light shielding portion 802, portions of the first connection electrode 211 and the second connection electrode 212 may be reused as the first light shielding portion 801, which may optimize the layout of the display substrate and make the overall design structure of the display substrate more compact. In some possible examples, in a structure in which the light shielding structure 108 includes a first light shielding portion 801 and a second light shielding portion 802, portions of the first connection electrode 211 and the second connection electrode 212 may be reused as the second light shielding portion 802. In some possible examples, in a structure in which the light shielding structure 108 includes only a first light shielding portion 801 or only a second light shielding portion 802, portions of the first connection electrode 211 and the second connection electrode 212 may be reused as the light shielding structure 108.

In an exemplary embodiment, the first connection electrode 211 and the second connection electrode 212 may be made of metallic material(s), such as any one or more of molybdenum (Mo), aluminum (Al), copper (Cu), and titanium (Ti). Alternatively, the first connection electrode 211 and the second connection electrode 212 may be made of an alloy material of metallic materials such as molybdenum (Mo), aluminum (Al), copper (Cu), and titanium (Ti), for example, an aluminum-neodymium alloy (AlNd) or a molybdenum-niobium alloy (MoNb). The first connection electrode 211 and the second connection electrode 212 may be a single-layer structure or a multi-layer composite structure, such as Ti/Al/Ti or the like.

In an exemplary embodiment, the second connection electrode 212 and the anode 501 of the light emitting device are not of an interconnected integral structure. The anode 501 may be made of a transparent conductive material, such as Indium Tin Oxide (ITO) or Indium Zinc Oxide (IZO), which may avoid the loss or shielding of the light emitted by the anode to the light emitting device and improve the light use efficiency of the display substrate.

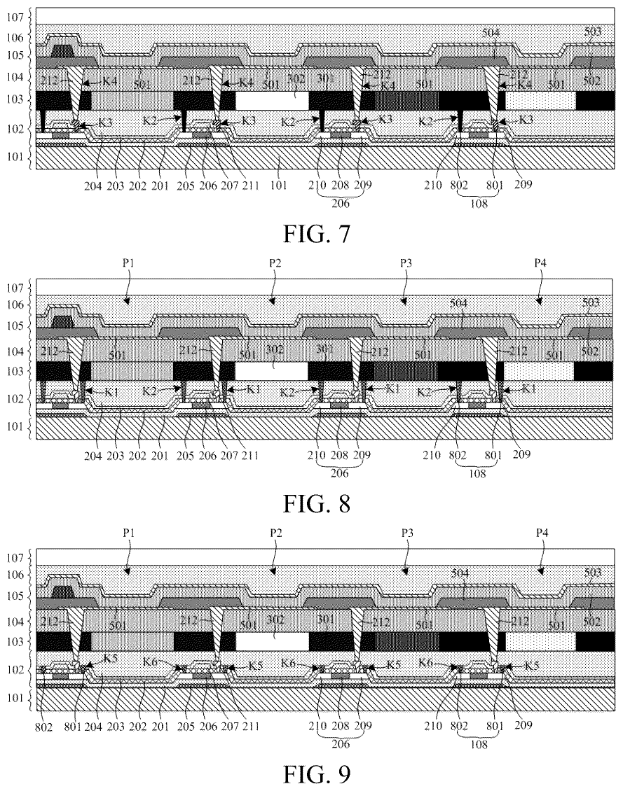

FIG. 7 is a schematic diagram of a sectional structure of a display substrate according to still another embodiment of the present disclosure. As shown in FIG. 7, in a plane perpendicular to the display substrate, each sub-pixel in the display substrate may include a base substrate 101, a drive circuit layer 102 provided on a side of the base substrate 101, a color film structure layer 103 provided on a side of the drive circuit layer 102 away from the base substrate 101, a first encapsulation layer 104 provided on a side of the color film structure layer 103 away from the base substrate 101, a light emitting structure layer 105 provided on a side of the first encapsulation layer 104 away from the base substrate 101, a second encapsulation layer 106 provided on a side of the light emitting structure layer 105 away from the base substrate 101, and a cover plate layer 107 provided on a side of the second encapsulation layer 106 away from the base substrate 101. The light emitting structure layer 105 may include a plurality of light emitting devices. The display substrate shown in FIG. 7 differs mainly from the aforementioned display substrate shown in FIG. 4 in that the first connection electrode 211 may be reused as at least a portion of the light shielding structure 108. In a structure in which the light shielding structure 108 includes a first light shielding portion 801 and a second light shielding portion 802, the first connection electrode 211 may be reused as the first light shielding portion 801, which may optimize the layout of the display substrate and make the overall design structure of the display substrate more compact. In some possible examples, in a structure in which the light shielding structure 108 includes a first light shielding portion 801 and a second light shielding portion 802, the first connection electrode 211 may be reused as the second light shielding portion 802. In some possible examples, in a structure in which the light shielding structure 108 includes only a first light shielding portion 801 or only a second light shielding portion 802, the first connection electrode 211 may be reused as the light shielding structure 108.

In some possible exemplary embodiments, a surface of the first connection electrode 211 facing away from the base substrate 101 may be flush with a surface of the fourth insulating layer 204 facing away from the base substrate 101. Alternatively, the surface of the first connection electrode 211 facing away from the base substrate 101 may be farther away from the base substrate 101 than the surface of the fourth insulating layer 204 facing away from the base substrate 101, which may increase a light shielding area of the first connection electrode, shorten the size of the second connection electrode along a thickness direction of the display substrate, which may also be referred to as the depth, and improve the connection reliability of the second connection electrode.

In an exemplary embodiment, the first connection electrode 211 may be made of metallic material(s), such as any one or more of molybdenum (Mo), aluminum (Al), copper (Cu), and titanium (Ti). Alternatively, the first connection electrode 211 may be made of an alloy material of metallic materials, such as molybdenum (Mo), aluminum (Al), copper (Cu), and titanium (Ti), for example, an aluminum-neodymium alloy (AlNd) or a molybdenum-niobium alloy (MoNb). The first connection electrode 211 may be a single-layer structure or a multi-layer composite structure, such as Ti/Al/Ti or the like.

In an exemplary embodiment, the second connection electrode 212 and the anode 501 of the light emitting device may be of an interconnected integral structure. The second connection electrode 212 and the anode 501 may be made of a transparent conductive material, such as Indium Tin Oxide (ITO) or Indium Zinc Oxide (IZO), which may avoid the loss or shielding of the light emitted by the anode to the light emitting device and improve the light use efficiency of the display substrate.

FIG. 8 is a schematic diagram of a sectional structure of a display substrate according to yet another embodiment of the present disclosure. As shown in FIG. 8, in a plane perpendicular to the display substrate, each sub-pixel in the display substrate may include a base substrate 101, a drive circuit layer 102 provided on a side of the base substrate 101, a color film structure layer 103 provided on a side of the drive circuit layer 102 away from the base substrate 101, a first encapsulation layer 104 provided on a side of the color film structure layer 103 away from the base substrate 101, a light emitting structure layer 105 provided on a side of the first encapsulation layer 104 away from the base substrate 101, a second encapsulation layer 106 provided on a side of the light emitting structure layer 105 away from the base substrate 101, and a cover plate layer 107 provided on a side of the second encapsulation layer 106 away from the base substrate 101. The light emitting structure layer 105 may include a plurality of light emitting devices. The display substrate shown in FIG. 8 differs mainly from the aforementioned display substrate shown in FIG. 4 in that the light shielding structure 108 and the black matrix 301 are not of an interconnected integral structure, and the light shielding structure 108 and the black matrix 301 may be made of the same material or of different materials. As shown in FIG. 8, a surface of the light shielding structure 108 facing away from the base substrate 101 may be flush with a surface of the fourth insulating layer 204 facing away from the base substrate 101.

FIG. 9 is a schematic diagram of a sectional structure of a display substrate according to still another embodiment of the present disclosure. As shown in FIG. 9, in a plane perpendicular to the display substrate, each sub-pixel in the display substrate may include a base substrate 101, a drive circuit layer 102 provided on a side of the base substrate 101, a color film structure layer 103 provided on a side of the drive circuit layer 102 away from the base substrate 101, a first encapsulation layer 104 provided on a side of the color film structure layer 103 away from the base substrate 101, a light emitting structure layer 105 provided on a side of the first encapsulation layer 104 away from the base substrate 101, a second encapsulation layer 106 provided on a side of the light emitting structure layer 105 away from the base substrate 101, and a cover plate layer 107 provided on a side of the second encapsulation layer 106 away from the base substrate 101. The light emitting structure layer 105 may include a plurality of light emitting devices. The display substrate shown in FIG. 9 differs mainly from the aforementioned display substrate shown in FIG. 4 in that the light shielding structure 108 and the black matrix 301 are not of an interconnected integral structure, and the light shielding structure 108 and the black matrix 301 may be made of the same material or of different materials. As shown in FIG. 9, a surface of the light shielding structure 108 facing away from the base substrate 101 is closer to the base substrate 101 than a surface of the fourth insulating layer 204 facing away from the base substrate 101. For example, the surface of the light shielding structure 108 facing away from the base substrate 101 may be flush with a surface of the third insulating layer 203 facing away from the base substrate 101. Alternatively, the surface of the light shielding structure 108 facing away from the base substrate 101 may be flush with a surface of the second insulating layer 202 facing away from the base substrate 101, or the like.

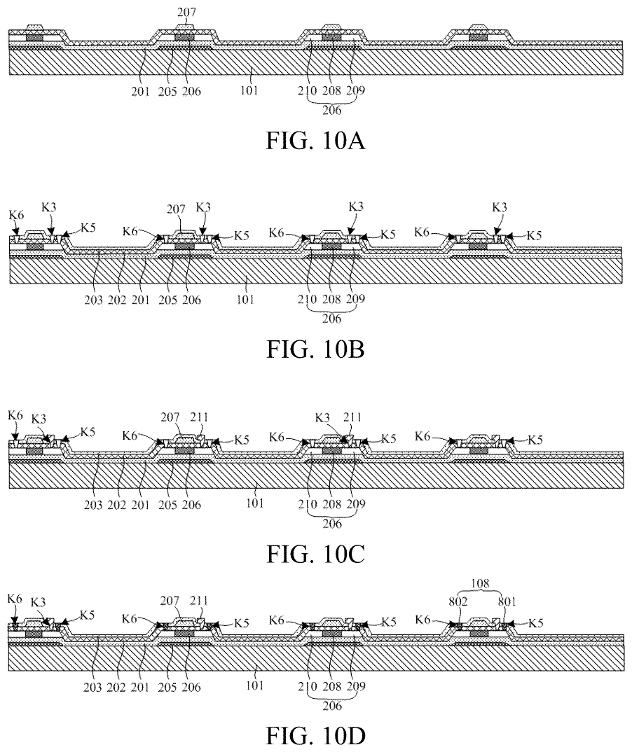

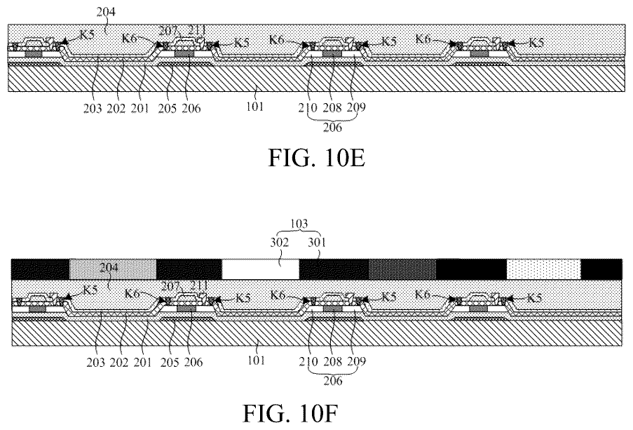

The preparation process of the display substrate may include the following steps. Taking the structure of the display substrate shown in FIG. 9 as an example, the preparation process of the display substrate is shown in FIGS. 10A to 10F:
(11) Providing a base substrate 101 and sequentially forming a pattern of a first conductive layer, a pattern of a first insulating layer, a pattern of a semiconductor layer, a second insulating film, and a pattern of a second conductive layer on a side of the base substrate 101, as shown in FIG. 10A. The first conductive layer may include a light shielding block 205, a data signal line, and the like. The semiconductor layer may include an active layer 206 of the transistor. Forming the pattern of the semiconductor layer may further include conducting a part of the active layer 206 such that portions of the active layer 206 form a first region 209 and a second region 210, respectively. The first region 209 of the active layer 206 may be used as a first electrode of the transistor, and the second region 210 of the active layer 206 may be used as a second electrode of the transistor. The second conductive layer may include a gate 207 of a transistor, a scan signal line, and the like.
(12) Forming a pattern of a third insulating layer. Forming the pattern of the third insulating layer may include depositing a third insulating film on the base substrate 101 on which the aforementioned patterns have been formed, and patterning the third insulating film and the second insulating film by a patterning process, to form a pattern of a second insulating layer provided on a side of the semiconductor layer and a pattern of a third insulating layer provided on a side of the second conductive layer, as shown in FIG. 10B, the third insulating layer 203 may be provided with at least one third opening K3, which penetrates the third insulating layer 203 and the second insulating layer 202 and exposes a portion of a surface of the first region 209. The third insulating layer 203 may be provided with at least one fifth opening K5 and sixth opening K6. The fifth opening K5 and the sixth opening K6 each may penetrate the third insulating layer 203 and the second insulating layer 202. The fifth opening K5 may cause at least a portion of a first light shielding portion formed subsequently to be located within the fifth opening K5, and the sixth opening K6 may cause at least a portion of a second light shielding portion formed subsequently to be located within the sixth opening K6.
(13) Forming a pattern of a third conductive layer. Forming the pattern of the third conductive layer may include depositing a third conductive film on the base substrate 101 on which the aforementioned patterns have been formed, and patterning the third conductive film by a patterning process, to form a pattern of a third conductive layer provided on a side of the third insulating layer 203, as shown in FIG. 10C, the third conductive layer may include a first connection electrode 211. The first connection electrode 211 may be connected to the first region 209 via the third opening K3.
(14) Forming a pattern of a light shielding structure layer. Forming the pattern of the light shielding structure layer may include depositing a light shielding film on the base substrate 101 on which the aforementioned patterns have been formed, and patterning the light shielding film by a patterning process, to form a pattern of a light shielding structure layer provided on a side of the third conductive layer, as shown in FIG. 10D. The light shielding structure layer includes a light shielding structure 108, and the light shielding structure 108 may include at least one of a first light shielding portion 801 and a second light shielding portion 802. FIG. 10D shows that the light shielding structure 108 includes a first light shielding portion 801, at least a portion of which may be located within the fifth opening K5, and a second light shielding portion 802, at least a portion of which may be located within the sixth opening K6.

In an exemplary embodiment, the light shielding structure 108 may be made of metallic material(s), such as any one or more of molybdenum (Mo), aluminum (Al), copper (Cu), and titanium (Ti). However, embodiments of the present disclosure are not limited to the materials used for the light shielding structure.
(15) Forming a pattern of a fourth insulating layer. Forming the pattern of the fourth insulating layer may include depositing a fourth insulating film on the base substrate 101 on which the aforementioned patterns have been formed, and patterning the fourth insulating film by a patterning process, to form a pattern of a fourth insulating layer located on a side of the third conductive layer, as shown in FIG. 10E.
(16) Forming a pattern of a color film structure layer. Forming the pattern of the color film structure layer may include coating a black pigment or depositing a black chromium (Cr) film on the base substrate 101 on which the aforementioned patterns have been formed, and patterning the black pigment or the black chromium film by a patterning process, to form a pattern of a black matrix located on a side of the fourth insulating layer 204, as shown in FIG. 10F.

Forming the pattern of the color film structure layer may further include forming a pattern of a filter layer located on a side of the fourth insulating layer 204 by means of photolithography or the like on the base substrate 101 on which the aforementioned patterns have been formed. The pattern of the filter layer may include a plurality of color filters 302. As shown in FIG. 10F, the color filters 302 and the black matrix 301 are located on the same side of the fourth insulating layer 204, and an orthographic projection of the color filters 302 on the display substrate does not overlap an orthographic projection of the black matrix 301 on the display substrate. The color filters 302 are provided in the red sub-pixel, the white sub-pixel, the blue sub-pixel, and the green sub-pixel, respectively, and filter white light emitted from the light emitting device into red (R) light, white (W) light, blue (B) light, and green (G) light, respectively.

The subsequent preparation process of the display substrate may refer to the aforementioned embodiments. In some possible embodiments, (13) forming a pattern of a third conductive layer and (14) forming a pattern of a light shielding structure layer in the above preparation process may be interchanged in order.

An embodiment of the present disclosure further provides a display apparatus, including the display substrate described in any one of the previous embodiments. The display apparatus may be any product or component with a display function, such as a mobile phone, a tablet computer, a television, a display, a laptop computer, a digital photo frame, and a navigator.

An embodiment of the present disclosure further provides a preparation method for a display substrate. By providing a light shielding structure in the display substrate, the problem of afterimage may be improved, and the yield of the display substrate may be improved. The preparation method for a display substrate provided by the embodiment of the present disclosure may be implemented by utilizing existing mature preparation equipment, which has the advantages of less modification on the existing process, simple preparation process, low production costs and high production precision, and has a good application prospect.

Although the embodiments disclosed in the present disclosure are described as above, the described contents are only embodiments which are adopted in order to facilitate understanding of the present disclosure, and are not intended to limit the present disclosure. It should be noted that the above examples or embodiments are exemplary only and not restrictive. Therefore, the present disclosure is not limited to what is specifically shown and described herein. Various modifications, substitutions or omissions may be made to the form and details of implementation without departing from the scope of the present disclosure.

1. A display substrate, comprising a base substrate, a drive circuit layer located on one side of the base substrate, and a light emitting structure layer located on a side of the drive circuit layer away from the base substrate, wherein the drive circuit layer comprises at least one pixel drive circuit, the at least one pixel drive circuit comprises at least one transistor, the transistor at least comprises an active layer, the drive circuit layer further comprises at least one insulating layer located on a side of the active layer away from the base substrate, and the light emitting structure layer comprises at least one light emitting device; and
the display substrate further comprises a light shielding structure, at least a portion of the light shielding structure is located in an opening provided in the at least one insulating layer, and the light shielding structure is configured to block light emitted by the at least one light emitting device from being emitted to a channel region of at least one active layer.

2. The display substrate according to claim 1, wherein the active layer further comprises a first region and a second region located on opposite sides of the channel region, and the light shielding structure is located between the active layer and the light emitting structure layer; and
the light shielding structure comprises at least one of a first light shielding portion and a second light shielding portion, an orthographic projection of the first light shielding portion on the display substrate is located within an orthographic projection of the first region on the display substrate, and an orthographic projection of the second light shielding portion on the display substrate is located within an orthographic projection of the second region on the display substrate.

3. The display substrate according to claim 2, wherein the at least one insulating layer is provided with at least one opening, the at least one opening comprises at least one of a first opening and a second opening, an orthographic projection of the first opening on the display substrate is located within an orthographic projection of the first region on the display substrate, and an orthographic projection of the second opening on the display substrate is located within an orthographic projection of the second region on the display substrate; and
wherein at least a portion of the first light shielding portion is located within the first opening, and at least a portion of the second light shielding portion is located within the second opening.

4. The display substrate according to claim 3, wherein a side of the first light shielding portion close to the active layer is in contact with the first region, and a side of the first light shielding portion away from the active layer is flush with a side of the at least one insulating layer away from the active layer.

5. The display substrate according to claim 3, wherein a side of the second light shielding portion close to the active layer is in contact with the second region, and a side of the second light shielding portion away from the active layer is flush with a side of the at least one insulating layer away from the active layer.

6. The display substrate according to claim 1, further comprising a color film structure layer located between the drive circuit layer and the light emitting structure layer, wherein the color film structure layer comprises a light shielding layer and a color filter, and the light shielding layer is provided in a same layer as the color filter.

7. The display substrate according to claim 6, wherein the light shielding layer comprises a black matrix, and at least a portion of the light shielding structure and the black matrix are of an interconnected integral structure.

8. The display substrate according to claim 6, wherein two adjacent color filters partially overlap and form an overlapping region located between two adjacent light emitting devices in a direction perpendicular to a plane of the display substrate.

9. The display substrate according to claim 1, wherein the light emitting device comprises a first electrode, an organic light emitting layer and a second electrode which are stacked, the first electrode is closer to the base substrate than the second electrode; and
the first electrode is connected to the active layer via a connection electrode, and a portion of the connection electrode is reused as at least a portion of the light shielding structure.

10. The display substrate according to claim 9, wherein the connection electrode comprises a first connection electrode and a second connection electrode which are stacked, the first connection electrode is closer to the base substrate than the second connection electrode, a first end of the first connection electrode is connected to the active layer, a second end of the first connection electrode is connected to the second connection electrode, and the second connection electrode is connected to the first electrode; and
wherein portions of the first connection electrode and the second connection electrode are reused as at least a portion of the light shielding structure.

11. The display substrate according to claim 9, wherein the connection electrode comprises a first connection electrode and a second connection electrode which are stacked, the first connection electrode is closer to the base substrate than the second connection electrode, a first end of the first connection electrode is connected to the active layer, a second end of the first connection electrode is connected to the second connection electrode, and the second connection electrode is connected to the first electrode; and
wherein the first connection electrode is reused as at least a portion of the light shielding structure.

12. The display substrate according to claim 11, wherein the second connection electrode and the first electrode are of an interconnected integral structure.

13. The display substrate according to claim 1, wherein the light emitting device comprises a first electrode, an organic light emitting layer and a second electrode which are stacked, the first electrode is closer to the base substrate than the second electrode, the light emitting device further comprises a pixel definition layer provided with a pixel opening, and the pixel opening exposes at least a portion of a surface of the first electrode; and
wherein at least a portion of the light shielding structure and the pixel definition layer are of an interconnected integral structure; or at least a portion of the light shielding structure and the organic light emitting layer are of an interconnected integral structure; or at least a portion of the light shielding structure and the second electrode are of an interconnected integral structure.

14. The display substrate according to claim 1, wherein the light shielding structure comprises a light shielding block, the drive circuit layer comprises a first conductive layer located on a side of the base substrate and a semiconductor layer located on a side of the first conductive layer away from the base substrate, the first conductive layer comprises at least one light shielding block, the semiconductor layer comprises at least one active layer, and an orthographic projection of the at least one light shielding block on the display substrate at least partially overlaps an orthographic projection of the channel region of the at least one active layer on the display substrate.

15. The display substrate according to claim 14, wherein the orthographic projection of the light shielding block on the display substrate comprises the orthographic projection of the channel region of the active layer on the display substrate.

16. The display substrate according to claim 1, wherein the drive circuit layer comprises a first conductive layer located on a side of the base substrate, a semiconductor layer located on a side of the first conductive layer away from the base substrate, and a second conductive layer located on a side of the semiconductor layer away from the base substrate, the semiconductor layer comprises at least one active layer, and the second conductive layer comprises a gate of the transistor; and
wherein an orthographic projection of the gate on the display substrate at least partially overlaps an orthographic projection of the channel region of the active layer on the display substrate.

17. The display substrate according to claim 16, wherein the orthographic projection of the gate on the display substrate comprises the orthographic projection of the channel region of the active layer on the display substrate.

18. The display substrate according to claim 16, wherein the light shielding structure comprises a light shielding block, the first conductive layer comprises at least one light shielding block, and the orthographic projection of the gate on the display substrate, the orthographic projection of the channel region of the active layer on the display substrate and an orthographic projection of the light shielding block on the display substrate are at least partially overlapped.

19. A display apparatus, comprising the display substrate according to claim 1.

20. A preparation method for a display substrate, for preparing the display substrate according to claim 1.
